(19) United States
(12) Patent Application Publication
(10) Pub. No.: US 2026/0305312 A1
(43) Pub. Date: Oct. 1, 2026

(54) PACKAGE STRUCTURE AND METHOD FOR MANUFACTURING THE SAME

(71) Applicant: NATIONAL YANG MING CHIAO TUNG UNIVERSITY, Hsinchu City (TW)

(72) Inventors: Chih CHEN, Hsinchu City (TW); Yu-Wen HUNG, Hsinchu City (TW)

(21) Appl. No.: 19/181,427

(22) Filed: Apr. 17, 2025

(30) Foreign Application Priority Data
Mar. 31, 2025 (TW) 114112297

(51) Int. Cl. H10W 20/44; H10W 20/00; H10W 20/41

(52) U.S. Cl. CPC H10W 20/4424; H10W 20/0526; H10W 20/0554; H10W 20/425

(57) ABSTRACT

A package structure comprises: a substrate; a first copper conductive element disposed on the substrate and having a first upper surface and two first side surfaces, wherein the two first side surfaces are opposite to each other and connected to the first upper surface respectively; and a first passivation layer formed on the first upper surface and the two first side surface of the first copper conductive element, wherein the first passivation later comprises Cu₃Sn.

### CROSS-REFERENCE TO RELATED APPLICATIONS

This application claims the benefits of the Taiwan Patent Application Serial Number 114112297, filed on Mar. 31, 2025, the subject matter of which is incorporated herein by reference.

### BACKGROUND OF THE INVENTION

### Field

The present invention relates to a package structure and a method for manufacturing the same. More specifically, the present invention relates to a package structure suitable for redistribution layer and a method for manufacturing the same.

### Description of Related Art

In the currently known packaging technologies, as the size of components reduces, in order to have greater flexibility in multi-die integration and more advanced die-to-die routing capacity, the requirements for mask size, line spacing of redistribution layer (RDL) and RDL layer number are becoming more stringent. RDL will be a key factor in 2.5D packaging and 3D packaging.

Copper is a common conductor material in RDL. If the copper conductive line is protected only by a dielectric layer, it is still very easy to be oxidized and corroded. In addition, metallization pattern still relies on lithography and etching processes to form under-bump metallization (UBM).

Furthermore, in high-power components, a larger cross-voltage is usually generated. If the conductive line does not have good withstand voltage insulation capability, it will have adverse effects, such as electrochemical migration (ECM), which will reduce the reliability of the high-power component.

Therefore, it is desirable to provide a novel package structure to solve the aforesaid problems.

### SUMMARY OF THE INVENTION

The present invention provides a package structure, which comprises: a substrate; a first copper conductive element disposed on the substrate and having a first upper surface and two first side surfaces, wherein the two first side surfaces are opposite to each other and respectively connected to the first upper surface; and a first passivation layer formed on the first upper surface and the two first side surfaces of the first copper conductive element, wherein the first passivation layer comprises Cu₃Sn.

The present invention further provides a method for manufacturing the aforesaid package structure, which comprises the following steps: providing a substrate, wherein a first copper conductive element is disposed on the substrate and has a first upper surface and two first side surfaces, and the two first side surfaces are opposite to each other and respectively connected to the first upper surface; forming a tin layer on the first upper surface and the two first side surfaces of the first copper conductive element; and performing an annealing process, wherein the tin layer and copper of the first copper conductive element undergo a phase change to form a first passivation layer on the first upper surface and two first side surfaces of the first copper conductive element, and the first passivation layer comprises Cu₃Sn.

Other novel features of the disclosure will become more apparent from the following detailed description when taken in conjunction with the accompanying drawings.

### BRIEF DESCRIPTION OF DRAWINGS

FIG. 1A to FIG. 1C are schematic views showing a process for manufacturing nano-twinned copper conductive lines according to Embodiment 1 of the present invention.

FIG. 2A to FIG. 2C are schematic views showing a process for manufacturing a package structure according to Embodiment 2 of the present invention.

FIG. 2D is a schematic view of a package structure according to Embodiment 3 of the present invention.

FIG. 3 is a FIB image of a package structure according to Embodiment 4 of the present invention.

FIG. 4 is a FIB image of a package structure according to Embodiment 5 of the present invention.

### DETAILED DESCRIPTION OF THE INVENTION

Different embodiments of the present invention are provided in the following description. These embodiments are meant to explain the technical content of the present invention, but not meant to limit the scope of the present invention. A feature described in an embodiment may be applied to other embodiments by suitable modification, substitution, combination, or separation.

It should be noted that, in the present specification, when a component is described to have an element, it means that the component may have one or more of the elements, and it does not mean that the component has only one of the element, except otherwise specified.

In the present specification, except otherwise specified, the feature A “or” or “and/or” the feature B means the existence of the feature A, the existence of the feature B, or the existence of both the features A and B. The feature A “and” the feature B means the existence of both the features A and B. The term “comprise(s)”, “comprising”, “include(s)”, “including”, “have”, “has” and “having” means “comprise(s)/comprising but is/are/being not limited to”.

Moreover, in the present specification, when an element is described to be arranged “on” another element, it does not essentially means that the elements contact the other element, except otherwise specified. Such interpretation is applied to other cases similar to the case of “on”.

Moreover, in the present specification, a value may be interpreted to cover a range within ±10% of the value, and in particular, a range within ±5% of the value, except otherwise specified. A range may be interpreted to be composed of a plurality of subranges defined by a smaller endpoint, a smaller quartile, a median, a greater quartile, and a greater endpoint, except otherwise specified.

In one embodiment, the present invention provides a package structure, comprising: a substrate; a first copper conductive element disposed on the substrate and having a first upper surface and two first side surfaces, wherein the two first side surfaces are opposite to each other and respectively connected to the first upper surface; and a first passivation layer formed on the first upper surface and the two first side surfaces of the first copper conductive element, wherein the first passivation layer comprises Cu₃Sn.

In one embodiment, the present invention provides a method for manufacturing a package structure, comprising the following steps: providing a substrate, wherein a first copper conductive element is disposed on the substrate and has a first upper surface and two first side surfaces, and the two first side surfaces are opposite to each other and respectively connected to the first upper surface; forming a tin layer on the first upper surface and the two first side surfaces of the first copper conductive element; and performing an annealing process, wherein the tin layer and copper of the first copper conductive element undergo a phase change to form a first passivation layer on the first upper surface and two first side surfaces of the first copper conductive element, and the first passivation layer comprises Cu₃Sn.

In the present invention, by forming a passivation layer including Cu₃Sn on the copper conductive element, the reliability of the package structure can be improved. More specifically, compared with the passivation layer formed by a polymer material, the Cu₃Sn intermetallic compound has a more compact structure, which is very beneficial to improving the reliability of the package structure.

However, in the known technology, the thickness of the Cu₃Sn intermetallic compound is very difficult to control, and it is difficult to evenly plate it on the upper surface and side surface of the copper conductive element. Therefore, in the present invention, a tin layer is formed on the copper conductive element, and then after annealing, the tin layer and the copper of the copper conductive element undergo a phase change, and a passivation layer including Cu₃Sn can be formed on the upper surface and the side surfaces of the conductive element. In particular, the Cu₃Sn passivation layer formed by the preparation method of the present invention is a continuous plating layer that is not easy to peel off and can evenly cover the upper surface and side surfaces of the copper conductive element, thereby preventing the copper conductive element from oxidation and corrosion, or preventing copper from dissociating to form copper ions and causing electromigration or electrochemical migration, thereby avoiding the problem of wire failure.

In one embodiment, the material of the substrate is not particularly limited and may comprise glass, quartz, sapphire, ceramics, polycarbonate (PC), polyimide (PI), polypropylene (PP), polyethylene terephthalate (PET), polymethylmethacrylate (PMMA), other suitable materials or a combination thereof, but the present invention is not limited thereto.

In one embodiment, a second copper conductive element may be further disposed on the substrate, and the second copper conductive element has a second upper surface and two second side surfaces, and the two second side surfaces are opposite to each other and respectively connected to the second upper surface. Herein, the method further comprises the following steps: forming the tin layer on the second upper surface and two second side surfaces of the second copper conductive element; and performing the annealing process, wherein the tin layer and copper of the second copper conductive element undergo a phase change to form a second passivation layer on the second upper surface and two second side surfaces of the second copper conductive element, wherein the second passivation layer comprises Cu₃Sn. Therefore, in one embodiment, the package structure may further comprise: a second copper conductive element disposed on the substrate and having a second upper surface and two second side surfaces, wherein the two second side surfaces are opposite to each other and respectively connected to the second upper surface; a second passivation layer disposed on the second upper surface and the two second side surfaces of the second copper conductive element, wherein the second passivation layer comprises Cu₃Sn.

In one embodiment, the first copper conductive element and the second copper conductive element are adjacent, and a gap between the first copper conductive element and the second copper conductive element may range from 0.05 μm to 20 μm, 0.05 μm to 15 μm, 0.05 μm to 10 μm or 0.1 μm to 10 μm. In one embodiment, the gap between the first copper conductive element and the second copper conductive element may be about 0.1 μm, 0.2 μm, 0.3 μm, 0.4 μm, 0.5 μm, 0.6 μm, 0.7 μm, 0.8 μm, 0.9 μm, 1 μm, 2 μm, 3 μm, 4 μm, 5 μm, 6 μm, 7 μm, 8 μm, 9 μm or 10 μm.

In one embodiment, widths of the first copper conductive element and the second copper conductive element may respectively range from 0.05 μm to 20 μm, 0.05 μm to 15 μm, 0.05 μm to 10 μm or 0.1 μm to 10 μm. In one embodiment, the widths of the first copper conductive element and the second copper conductive element may respectively be about 0.1 μm, 0.2 μm, 0.3 μm, 0.4 μm, 0.5 μm, 0.6 μm, 0.7 μm, 0.8 μm, 0.9 μm, 1 μm, 2 μm, 3 μm, 4 μm, 5 μm, 6 μm, 7 μm, 8 μm, 9 μm or 10 μm.

In one embodiment, lengths of the first copper conductive element and the second copper conductive element are not particularly limited and may be adjusted according to the needs.

In one embodiment, thicknesses of the first copper conductive element and the second copper conductive element are not particularly limited and may be adjusted according to the needs. In one embodiment, thicknesses of the first copper conductive element and the second copper conductive element may respectively range from 0.05 μm to 20 μm, 0.05 μm to 15 μm, 0.05 μm to 10 μm or 0.1 μm to 10 μm. In one embodiment, the thicknesses of the first copper conductive element and the second copper conductive element may respectively be about 0.1 μm, 0.2 μm, 0.3 μm, 0.4 μm, 0.5 μm, 0.6 μm, 0.7 μm, 0.8 μm, 0.9 μm, 1 μm, 2 μm, 3 μm, 4 μm, 5 μm, 6 μm, 7 μm, 8 μm, 9 μm or 10 μm.

In one embodiment, the first copper conductive element and the second copper conductive element may respectively be a copper conductive line. In one embodiment, the first copper conductive element and the second copper conductive element may respectively comprise twinned copper, for example, nano-twinned copper. In one embodiment, the first copper conductive element and the second copper conductive element may respectively be a twinned copper conductive line, for example, a nano-twinned copper conductive line.

In one embodiment, twinned copper or nano-twinned copper may comprise a plurality of twinned grains, and at least part of the twinned grains are formed by stacking plural nano-twins along a [111] crystal axis.

In one embodiment, more than 50% of the volume of the twinned copper or nano-twinned copper may comprise a plurality of twinned grains. In one embodiment, for example, 50% to 99%, 60% to 99%, 70% to 99%, 80% to 99%, 80% to 95%, 85% to 95% or 90% to 95% of the volume of the twinned copper or nano-twinned copper may comprise a plurality of twinned grains; but the present invention is not limited thereto.

In the present invention, the so-called “twin direction of the twinned grains” refers to the stacking direction of twin planes in twinned grains, wherein the twin planes of the twinned grains may be substantially perpendicular to the stacking direction of the twin planes.

In one embodiment, the first passivation layer may be formed on the first upper surface and two first side surfaces of the first copper conductive element, and for example, the first passivation layer may completely cover the first upper surface and two first side surfaces of the first copper conductive element. In addition, in one embodiment, the second passivation layer may be formed on the second upper surface and two second side surfaces of the second copper conductive element, and for example, the second passivation layer may completely cover the second upper surface and two second side surfaces of the second copper conductive element.

In one embodiment, thicknesses of the first passivation layer and the second passivation layer may respectively range from 50 nm to 500 nm, for example, 60 nm to 500 nm, 70 nm to 500 nm, 80 nm to 500 nm, 90 nm to 500 nm, 100 nm to 500 nm, 150 nm to 500 nm or 200 nm to 500 nm.

In one embodiment, the thicknesses of the first passivation layer and the second passivation layer can be adjusted by the thickness of the tin layer or the time or temperature of the annealing process. In one embodiment, the temperature of the annealing process may range from 150° C. to 500° C., 180° C. to 500° C., 180° C. to 450° C., 200° C. to 450° C., 200° C. to 400° C., 230° C. to 400° C., 230° C. to 380° C., 250° C. to 380° C. or 250° C. to 300° C. The time of the annealing process may be adjusted according to the temperature of the annealing process and the thickness of the tin layer, to obtain the first passivation layer and the second passivation layer with desired thicknesses.

### Embodiment 1—Preparation of Nano-Twinned Copper Conductive Line

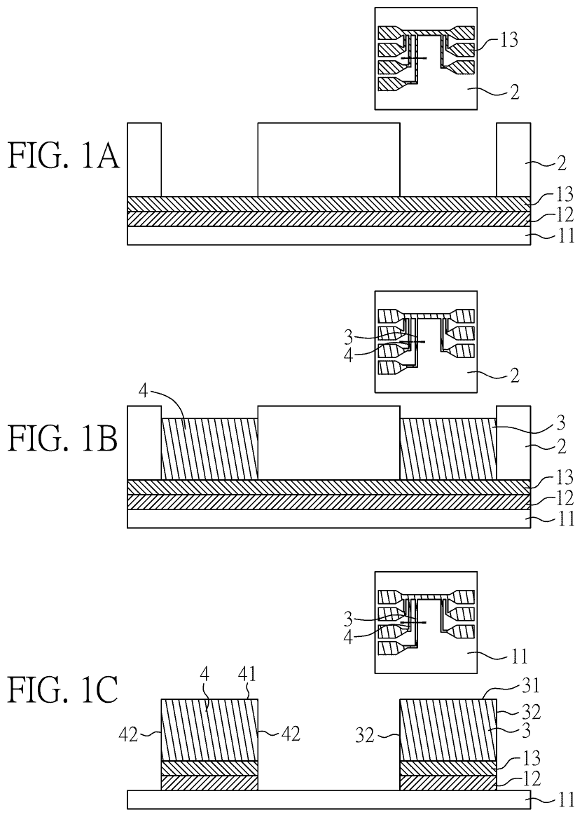

FIG. 1A to FIG. 1C are schematic views showing a process for manufacturing nano-twinned copper conductive lines according to Embodiment 1 of the present invention.

As shown in FIG. 1A, a substrate 11 is provided. In the present embodiment, the substrate 11 is an 8-inch silicon wafer, and 100 nm titanium (as an adhesion layer 12) and 200 nm copper (as a seed layer 13) are sputtered on the silicon wafer in sequence. Next, a photoresist layer 2 is formed, and a RDL pattern is defined through a lithography process. Then, the substrate 11 with the patterned photoresist layer 2 is cut into test pieces with suitable size for electroplating.

In the present embodiment, the plating solution used is composed of 95% copper sulfate pentahydrate powders, 97% sulfuric acid, 38% hydrochloric acid and additives. The content of each component is 196.61 g/L copper sulfate pentahydrate powders, 100 g/L sulfuric acid, 0.1 ml/L hydrochloric acid and additives. Finally, deionized water is added to make the total solution one liter. Then, a magnetic stirrer is used to stir the solution to make it evenly mixed. After completion, the plating solution is poured into the plating tank and the magnetic stirring speed is set to 1200 rpm so that the plating solution can flow evenly during the plating process. The plating is carried out at room temperature under atmospheric pressure. The cathode is the test piece prepared above, the anode is a conductive copper target, and a software-controlled power supply is used. The test piece is placed at the cathode end for electroplating in a constant current periodic reverse pulse mode, and nano-twinned copper conductive lines are electroplated at the position defined by the patterned photoresist layer 2, as shown in FIG. 1B. Then, the photoresist layer 2, the seed layer 13 and the adhesion layer 12 are removed by an organic solvent and an etching solution respectively, and the Cu-RDL test piece is completed, as shown in FIG. 1C.

As shown in FIG. 1C, a first copper conductive element 3 is disposed on the substrate 11 and has a first upper surface 31 and two first side surfaces 32, and the two first side surfaces 32 are opposite to each other and respectively connected to the first upper surface 31. In addition, a second copper conductive element 4 is further disposed on the substrate 11, the second copper conductive element 4 has a second upper surface 41 and two second side surfaces 42, and the two second side surfaces 42 are opposite to each other and respectively connected to the second upper surface 41. Herein, the first copper conductive element 3 and the second copper conductive element 4 respectively a nano-twinned copper conductive line.

In other embodiments of the present invention, after electroplating the nano-twinned copper conductive lines, as shown in FIG. 1B and FIG. 1C, the seed layer 13 may be integrated with the first copper conductive element 3 and the second copper conductive element 4, and the seed layer 13 may not be observed. In other words, after electroplating the nano-twinned copper conductive lines, the seed layer 13 may not be included below the first copper conductive element 3 and the second copper conductive element 4.

### Embodiment 2—Preparation of Package Structure

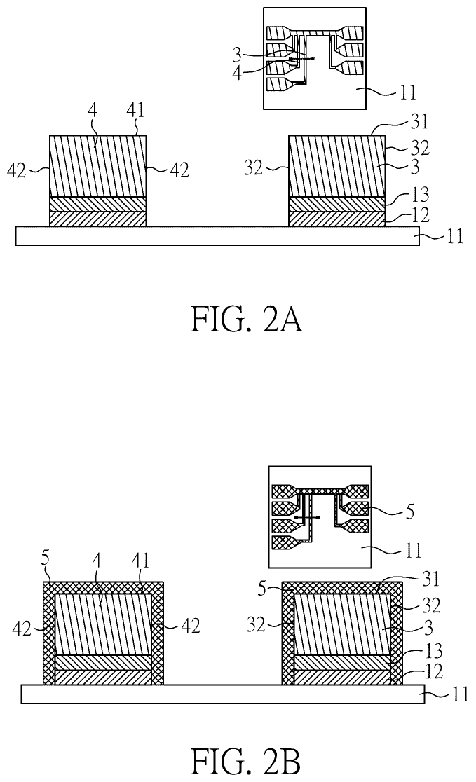

FIG. 2A to FIG. 2C are schematic views showing a process for manufacturing a package structure according to Embodiment 2 of the present invention.

As shown in FIG. 2A, a substrate 11 is provided, and a first copper conductive element 3 and a second copper conductive element 4 are disposed thereon. In the present embodiment, the structure shown in FIG. 2A is similar to that shown in FIG. 1C, and is not described again here.

Next, as shown in FIG. 2B, a tin layer 5 is formed on the first upper surface 31 and two first side surfaces 32 of the first copper conductive element 3. In addition, the tin layer 5 is further formed on the second upper surface 41 and two second side surfaces 42 of the second copper conductive element 4.

In the present embodiment, immersion tin plating is performed using commercially available immersion plating solutions to deposit the tin layer 5 on the first upper surface 31 and the two first side surfaces 32 of the first copper conductive element 3 as well as the second upper surface 41 and the two second side surfaces 42 of the second copper conductive element 4.

Next, as shown in FIG. 2C, an annealing process is performed, wherein the tin layer 5 and copper in the first copper conductive element 3 undergo a phase change to form a first passivation layer 61 on the first upper surface 31 and the two first side surfaces 32 of the first copper conductive element 3, wherein the first passivation layer 61 comprises Cu₃Sn. Similarly, the tin layer 5 and copper in the second copper conductive element 4 undergo a phase change to form a second passivation layer 62 on the second upper surface 41 and the two second side surfaces 42 of the second copper conductive element 4, wherein the second passivation layer 62 comprises Cu₃Sn.

In the present embodiment, the annealing process is performed at 300° C. for 5 hours in a vacuum environment to cause a phase change between the tin layer 5 and the copper of the first copper conductive element 3 and the second copper conductive element 4. The tin layer 5 on the first upper surface 31, the two first side surfaces 32, the second upper surface 41 and the two second side surfaces 42 are converted into Cu₃Sn to serve as the first passivation layer 61 and the second passivation layer 62. In order to avoid cracking caused by thermal stress, furnace cooling is used for cooling. The formed Cu₃Sn layer is a continuous intermetallic compound passivation layer that can protect the internal copper conductive elements (i.e., nano-twinned copper conductive lines) and prevent environmental corrosion and oxidation of the Cu-RDL.

In addition, the results of the component analysis of energy-dispersive X-ray spectroscopy (EDS) shows that the atomic percentage ratio of Cu and Sn in the passivation layer (i.e., the first passivation layer 61 and the second passivation layer 6) is close to 3 to 1, proving that the material of the formed continuous passivation layer is Cu₃Sn.

After the aforesaid steps, the package structure of the present embodiment can be obtained. As shown in FIG. 2C, the package structure of the present embodiment comprises: a substrate 11; a first copper conductive element 3 disposed on the substrate 11 and having a first upper surface 31 and two first side surfaces 32, wherein the two first side surfaces 32 are opposite to each other and respectively connected to the first upper surface 31; and a first passivation layer 61 formed on the first upper surface 31 and two first side surfaces 32 of the first copper conductive element 3, wherein the first passivation layer 61 comprises Cu₃Sn. More specifically, the first passivation layer 61 completely covers the first upper surface 31 and two first side surfaces 32 of the first copper conductive element 3.

In addition, the package structure of the present embodiment further comprises: a second copper conductive element 4 disposed on the substrate 11 and having a second upper surface 41 and two second side surfaces 42, wherein the two second side surfaces 42 are opposite to each other and respectively connected to the second upper surface 41; a second passivation layer 62 formed on the second upper surface 41 and two second side surfaces 42 of the second copper conductive element 4, wherein the second passivation layer 62 comprises Cu₃Sn. More specifically, the second passivation layer 62 completely covers the second upper surface 41 and two second side surfaces 42 of the second copper conductive element 4.

In addition, the first copper conductive element 3 and the second copper conductive element 4 are adjacent, and a gap G between the first copper conductive element 3 and the second copper conductive element 4 ranges from 0.05 μm to 20 μm.

In the present embodiment, as shown in FIG. 2A to FIG. 2C, the seed layer 13 is disposed under the first copper conductive element 3 and the second copper conductive element 4. However, in other embodiments of the present invention, the seed layer 13 may be integrated with the first copper conductive element 3 and the second copper conductive element 4, and the seed layer 13 may not be observed. In other words, the seed layer 13 may not be included below the first copper conductive element 3 and the second copper conductive element 4.

### Embodiment 3—Package Structure

FIG. 2D is a schematic view of a package structure according to Embodiment 3 of the present invention.

The package structure of the present embodiment is similar to that shown in FIG. 2C. The difference is that the package structure of the present embodiment further comprises: a protection layer 7 disposed on the first passivation layer 61 and the second passivation layer 62, wherein the protection layer 7 may comprise a polymer material such as polyimide (PI); but the present invention is not limited thereto.

In the present embodiment, as shown in FIG. 2D, the seed layer 13 is disposed under the first copper conductive element 3 and the second copper conductive element 4. However, in other embodiments of the present invention, the seed layer 13 may be integrated with the first copper conductive element 3 and the second copper conductive element 4, and the seed layer 13 may not be observed. In other words, the seed layer 13 may not be included below the first copper conductive element 3 and the second copper conductive element 4.

### Embodiment 4

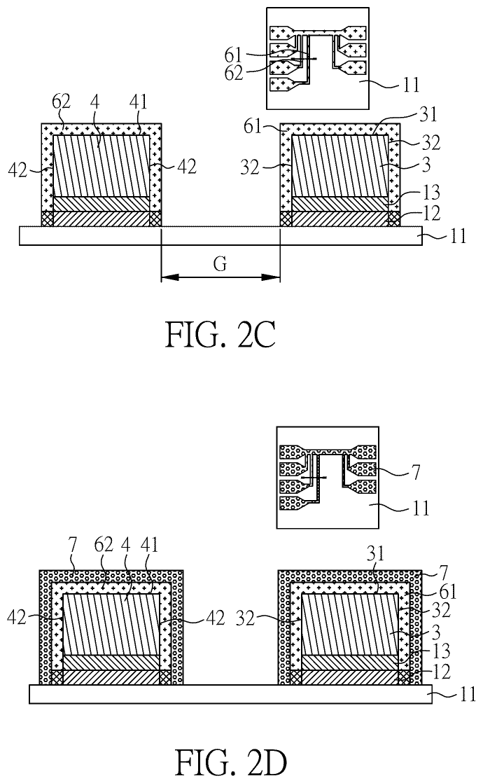

FIG. 3 is a focus ion beam (FIB) image of a package structure according to Embodiment 4 of the present invention. Herein, the package structure of the present embodiment can be formed by a similar method for manufacturing a package structure described in Embodiment 2. In FIG. 3, Pt is mainly used as a protection layer for protecting Cu₃Sn during cutting for forming cross-section for FIB analysis.

In the present embodiment, the copper conductive element is a nano-twinned copper conductive line with a line length of about 800 μm, a line width of about 10 μm, and a thickness of about 5 μm. As shown in FIG. 3, the thickness of the Cu₃Sn passivation layer is about 500 nm.

In addition, the nano-twinned copper conductive line comprises a plurality of twinned grains, wherein at least part of the twinned grains are formed by stacking plural nano-twins along a [111] crystal axis, more than 80% of the volume comprises a plurality of twinned grains, and the twin planes of the twinned grains are substantially perpendicular to the stacking direction of the twin planes.

Embodiment 5

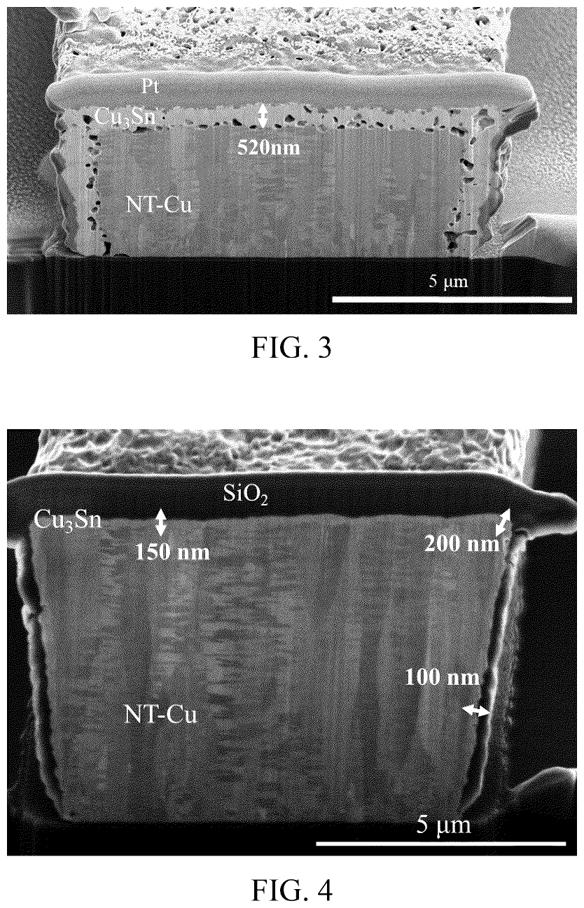

FIG. 4 is a focus ion beam (FIB) image of a package structure according to Embodiment 5 of the present invention. Herein, the package structure of the present embodiment can be formed by a similar method for manufacturing a package structure described in Embodiment 2. In FIG. 4, SiO₂ is mainly used as a protection layer for protecting Cu₃Sn during cutting for forming cross-section for FIB analysis.

In the present embodiment, the copper conductive element is a nano-twinned copper conductive line with a line length of about 800 μm, a line width of about 10 μm, and a thickness of about 5 μm. As shown in FIG. 4, the thickness of the Cu₃Sn passivation layer is about 100-200 nm, and thickness of the thinnest part of the Cu₃Sn passivation layer is about 50 nm.

In addition, the nano-twinned copper conductive line comprises a plurality of twinned grains, wherein at least part of the twinned grains are formed by stacking plural nano-twins along a [111] crystal axis, more than 80% of the volume comprises a plurality of twinned grains, and the twin planes of the twinned grains are substantially perpendicular to the stacking direction of the twin planes.

In summary, the present invention utilizes immersion plating technology and annealing treatment to cover Cu₃Sn as a passivation layer on a copper conductive element (for example, a copper conductive line having a twinned copper structure). Herein, the thickness of the Cu₃Sn passivation layer can be adjusted with parameters. In addition, the Cu₃Sn passivation layer can completely cover the upper surface and both side surfaces of the copper conductive element (for example, a copper conductive line having a twinned copper structure), effectively preventing oxidation and corrosion of the copper conductive element and improving the reliability of the packaged chip. In particular, the present invention can adjust the thickness of the Cu₃Sn passivation layer by adjusting the thickness of the tin layer and the temperature and time of the annealing process. Therefore, the package structure and the method for manufacturing the same of the present invention can be applied to 2.5D and 3D packaging, especially in RDL with fine line width or high density.

Although the present disclosure has been explained in relation to its embodiment, it is to be understood that many other possible modifications and variations can be made without departing from the spirit and scope of the disclosure as hereinafter claimed.

1. A package structure, comprising:
a substrate;
a first copper conductive element disposed on the substrate and having a first upper surface and two first side surfaces, wherein the two first side surfaces are opposite to each other and respectively connected to the first upper surface; and
a first passivation layer formed on the first upper surface and the two first side surfaces of the first copper conductive element, wherein the first passivation layer comprises Cu₃Sn.

2. The package structure of claim 1, wherein the first passivation layer completely covers the first upper surface and the two first side surfaces of the first copper conductive element.

3. The package structure of claim 1, wherein the first copper conductive element is a copper conductive line.

4. The package structure of claim 1, wherein a thickness of the first passivation layer ranges from 50 nm to 500 nm.

5. The package structure of claim 1, wherein the first copper conductive element comprises nano-twinned copper.

6. The package structure of claim 1, wherein a width of the first copper conductive element ranges from 0.05 μm to 20 μm.

7. The package structure of claim 1, further comprising:
a second copper conductive element disposed on the substrate and having a second upper surface and two second side surfaces, wherein the two second side surfaces are opposite to each other and respectively connected to the second upper surface;
a second passivation layer formed on the second upper surface and the two second side surface of the second copper conductive element, wherein the second passivation layer comprises Cu₃Sn,
wherein the first copper conductive element and the second copper conductive element are adjacent, and a gap between the first copper conductive element and the second copper conductive element ranges from 0.05 μm to 20 μm.

8. The package structure of claim 7, wherein the second copper conductive element comprises nano-twinned copper.

9. A method for manufacturing a package structure, comprising the following steps:
providing a substrate, wherein a first copper conductive element is disposed on the substrate and has a first upper surface and two first side surfaces, and the two first side surfaces are opposite to each other and respectively connected to the first upper surface;
forming a tin layer on the first upper surface and the two first side surfaces of the first copper conductive element; and
performing an annealing process, wherein the tin layer and copper of the first copper conductive element undergo a phase change to form a first passivation layer on the first upper surface and two first side surfaces of the first copper conductive element, and the first passivation layer comprises Cu₃Sn.

10. The method of claim 9, wherein the first passivation layer completely covers the first upper surface and the two first side surfaces of the first copper conductive element.

11. The method of claim 9, wherein the first copper conductive element is a copper conductive line.

12. The method of claim 9, wherein a thickness of the first passivation layer ranges from 50 nm to 500 nm.

13. The method of claim 9, wherein the first copper conductive element comprises nano-twinned copper.

14. The method of claim 9, wherein a width of the first copper conductive element ranges from 0.05 μm to 20 μm.

15. The method of claim 9, wherein a second copper conductive element is further disposed on the substrate, the second copper conductive element has a second upper surface and two second side surfaces, and the two second side surfaces are opposite to each other and respectively connected to the second upper surface,
wherein the method further comprises the following steps:
forming the tin layer on the second upper surface and two second side surfaces of the second copper conductive element; and
performing the annealing process, wherein the tin layer and copper of the second copper conductive element undergo a phase change to form a second passivation layer on the second upper surface and two second side surfaces of the second copper conductive element, and the second passivation layer comprises Cu₃Sn,
wherein the first copper conductive element and the second copper conductive element are adjacent, and a gap between the first copper conductive element and the second copper conductive element ranges from 0.05 μm to 20 μm.

16. The method of claim 15, wherein the second copper conductive element comprises nano-twinned copper.
